(19) United States
(12) Patent Application Publication
(10) Pub. No.: US 2026/0129969 A1
(43) Pub. Date: May 7, 2026

(54) SEMICONDUCTOR STRUCTURE AND MANUFACTURING METHOD THEREOF

(71) Applicant: TAIWAN SEMICONDUCTOR MANUFACTURING COMPANY LTD., HSINCHU (TW)

(72) Inventor: JHON JHY LIAW, HSINCHU COUNTY (TW)

(21) Appl. No.: 18/939,573

(22) Filed: Nov. 7, 2024

(51) Int. Cl. H01L 27/118; H03K 3/356; H03K 19/20

(52) U.S. Cl. CPC H10D 84/907; H03K 3/356104; H03K 19/20; H10D 84/953; H10D 84/981

(57) ABSTRACT

A semiconductor structure is provided. The semiconductor structure includes a transistor, a contact and a power supply line. The transistor includes a gate structure having a plurality of semiconductor layers extending along a first direction and vertically stacked along a second direction in a device region, and a first source/drain region and a second source/drain region on opposite sides of the gate structure. The contact is formed on a back-side of the first source/drain region. The power supply line is formed on a back-side of the device region and electrically connected to the contact. A first dielectric layer is in contact with sidewall of the contact, and the first dielectric layer extends from the power supply line to contact the first source/drain region. A second dielectric layer is in contact with sidewall of the first dielectric layer close to the power supply line.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, gate-all-around (GAA) transistors have been incorporated into memory devices (including, for example, static random-access memory, or SRAM, cells) and core devices (including, for example, standard logic, or STD, cells) to reduce chip footprint while maintaining reasonable processing margins.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIG. 1A shows a logic symbol of a standard cell NAND.

FIG. 1B shows a circuit diagram of the standard cell NAND of FIG. 1A.

FIG. 2A shows a logic symbol of a standard cell INV (inverter).

FIG. 2B shows a circuit diagram of the standard cell INV of FIG. 2A.

FIG. 3 is schematic view of a wafer including a front-side interconnect structure and a back-side interconnect structure on a device region thereof, in accordance with some embodiments of the disclosure.

FIGS. 4A and 4B illustrate a layout diagram of a logic circuit on a front side and a back-side of a semiconductor structure, respectively, in accordance with some embodiments of the disclosure.

FIGS. 5A, 5B-1, 5C, 5D, 5E, 5F-1, 5G, and 5H illustrate cross-sectional views obtained from reference cross-sections C1-C1′, C2-C2′, C3-C3′, C4-C4′, C5-C5′, C6-C6′, C7-C7′, and C8-C8′ in FIGS. 4A and 4B.

FIGS. 5B-2 and 5F-2 illustrate cross-sectional views of a semiconductor structure corresponding to FIGS. 5B-1 and 5F-1, respectively, in accordance with some embodiments of the disclosure.

FIGS. 6A-6G illustrate cross-sectional views of intermediate stages in the formation of back-side contact, in accordance with some embodiments.

FIGS. 7A and 7B illustrate a layout diagram of a logic circuit on a front side and a back-side of a semiconductor structure, respectively, in accordance with some embodiments of the present disclosure.

FIGS. 8A and 8B illustrate cross-sectional views obtained from reference cross-sections C1-C1′ and C2-C2′, respectively, in FIGS. 7A and 7B.

### DETAILED DESCRIPTION

The following disclosure provides many different embodiments, or examples, for implementing different features of the provided subject matter. Specific examples of components and arrangements are described to simplify the disclosure. These are, of course, merely examples and are not intended to be limiting. For example, the formation of a first feature over or on a second feature in the description that follows may include embodiments in which the first and second features are formed in direct contact, and may also include embodiments in which additional features may be formed therebetween. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “above,” “upper,” “lower,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The present disclosure is generally related to semiconductor devices, and more particularly to circuit cells having field-effect transistors (FETs), such as gate-all-around (GAA) transistors, in an integrated circuit (IC) structure. Generally, a GAA transistor may include a plurality of vertically stacked sheets (e.g., nanosheets), wires (e.g., nanowires), or rods (e.g., nanorods) in a channel region of the transistor, thereby allowing better gate control, lowered leakage current, and improved scaling capability for various IC applications.

The nanostructure transistor (e.g. nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The GAA transistor allows for more aggressive gate length scaling for both performance and density improvement. The GAA transistor has vertically-stacked horizontal semiconductor nanowires/nanosheets with extremely narrow cylindrical or sheet channel body. Due to better gate control ability, lower leakage current, shrink capability and fully FinFET device layout comparable, the GAA transistor has become a best candidate for future generation and low supply voltage applications. Furthermore, the GAA transistor formed by semiconductor nanosheet has wider channel width for high speed application.

Embodiments of semiconductor structures are provided. The semiconductor structures includes a metal line routing structure and method in the back-side interconnect structure to improve the functional density and operation performance on the IC structure. Because the power conductive contact can be formed to inherit the location of the dielectric layer directly underlying the source/drain region, the back-side contact can self-align with the source/drain region to connect the source/drain region to the back-side power metal layers. Therefore, by using the self-aligned back-side contact structure including the two-stage dielectric formed by the thinner dielectric layer and the thicker dielectric layer, the isolation margin between the back-side contact and the gate electrode is solved, thereby allowing continuous contact poly pitch (CPP) scaling.

In an integrated circuit (IC), a logic circuit is configured to perform a specific function or operation. The logic circuit includes multiple logic cells. In some embodiments, the logic cell may be a standard cell (STD cell). In such embodiments, the logic cells form a cell array, and the logic cells have the same cell height. In some embodiments, the cell array is capable of performing a specific function. In some embodiments, the logic cells is capable of performing various functions. In some embodiments, the logic cells are the standard cells (e.g., inverter (INV), AND, OR, NAND, NOR, Flip-Flop, SCAN, etc.), a combination thereof or specific functional cells. Furthermore, each logic cell includes multiple transistors, i.e., P-type and N-type transistors. In some embodiments, the logic cells corresponding to the same function or operation may have the same circuit configuration.

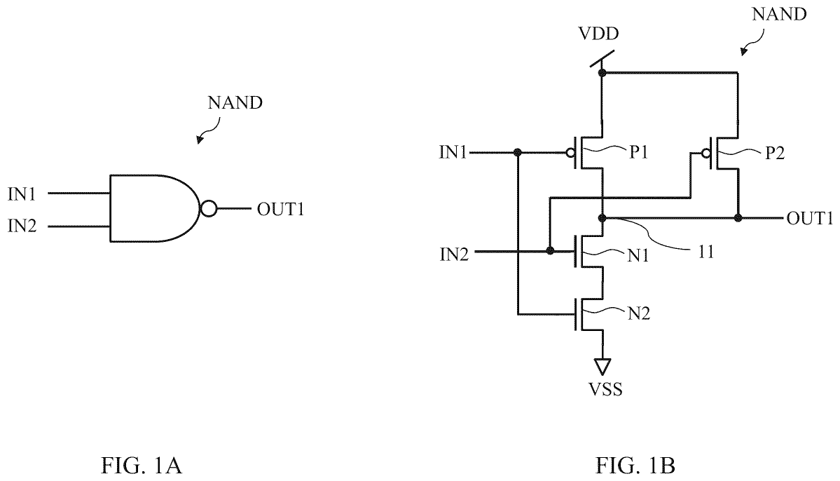

FIG. 1A shows a logic symbol of a standard cell NAND, and FIG. 1B shows a circuit diagram of the standard cell NAND of FIG. 1A. The standard cell NAND is a logic gate configured to provide an output signal OUT1 according two input signals IN1 and IN2. The standard cell NAND includes two P-type transistors P1 and P2 and two N-type transistors N1 and N2. In the standard cell NAND, the P-type transistors P1 and P2 are coupled in parallel between a node 11 and a power supply VDD. The N-type transistor N1 is coupled between the node 11 and the N-type transistor N2, and the N-type transistor N2 is coupled between the N-type transistor N1 and a ground VSS. The input signal IN1 is input to the gates of the P-type transistor P1 and the N-type transistor N1, and the input signal IN2 is input to the gates of the P-type transistor P2 and the N-type transistor N2. Furthermore, the output signal OUT1 is provided at the node 31.

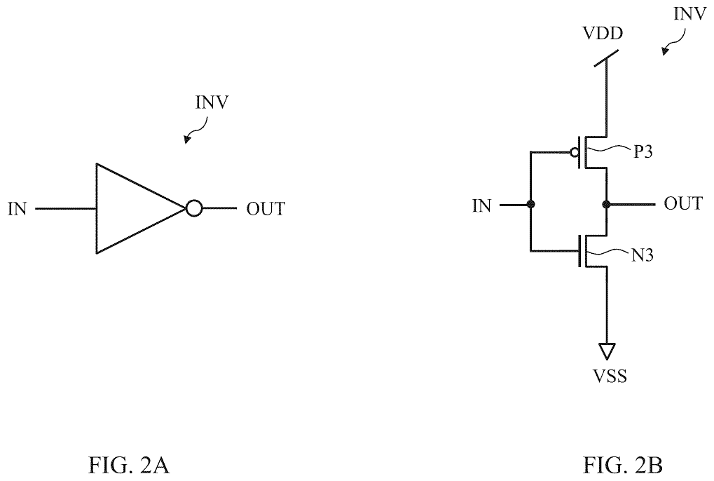

FIG. 2A shows a logic symbol of a standard cell INV (i.e., inverter), and FIG. 2B shows a circuit diagram of the standard cell INV of FIG. 2A. The standard cell INV is a logic gate configured to inverting an input signal IN to provide an output signal OUT. The standard cell INV includes a P-type transistor P3 and an N-type transistor N3. In the standard cell INV, the P-type transistor P3 is coupled between the N-type transistor N3 and a power supply VDD, and the N-type transistor N3 is coupled between the P-type transistor P3 and a ground VSS. The input signal IN is input to the gates of the P-type transistor P3 and the N-type transistor N3. Furthermore, the output signal OUT is provided at the drains of the N-type transistor N3 and the P-type transistor P3.

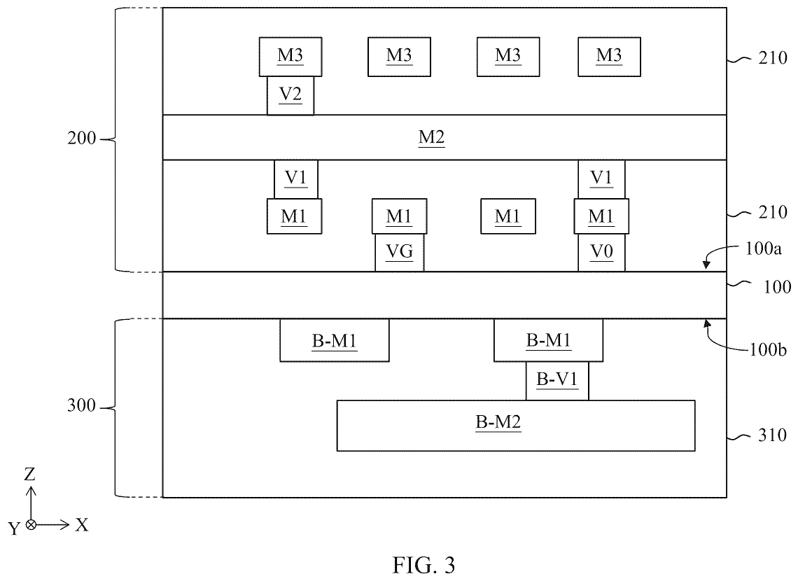

FIG. 3 is schematic view of a wafer including a front-side interconnect structure 200 and a back-side interconnect structure 300 on a device region 100 thereof, in accordance with some embodiments of the disclosure. The device region 100 (also referred to as a device layer) is the region where the transistors and the main features are located, such as the gate, channel, source/drain, contact features, and the transistors (e.g., the N-type transistors N1 to N3, and the P-type transistors P1 to P3) of the logic cells discussed above. The device region 100 has a front-side 100a and a back-side 100b.

The back-side interconnect structure 300 is under the device region 100 or on the back-side 100b of the device region 100, and the front-side interconnect structure 200 is over the device region 100 or on the front side 100a of the device region 100. The back-side interconnect structure 300 includes an inter-metal dielectric (IMD) layer 310, the via B-V1, and the metal lines B-M1 and B-M2. The front-side interconnect structure 200 includes the IMD layer 210, the vias VG, V0, V1 and V2, and the metal lines M1, M2 and M3. The vias and metal lines in the IMD layer 310 and the IMD layer 210 are electrically coupled to various transistors (e.g., the N-type transistors N1 to N3, and the P-type transistors P1 to P3, other transistors) and/or components (e.g., the gate, source/drain features, resistors, capacitors, and/or inductors) in the device region 100, such that the various devices and/or components can operate as specified by design requirements of logic cell (e.g., INV, NAND, NOR, flip-flop, SCAN, other logic cells, or other STD cells). It should be noted that there may be more vias and metal lines in the IMD layer 210 and the IMD layer 310 for connections. The IMD layers 210 and 310 may be multilayer structure, such as one or more dielectric layers.

In the back-side interconnect structure 300, the IMD layer 310, the via B_V1, and the metal lines B_M1, B_M2 may also be referred to as the back-side IMD, the back-side vias, and the back-side metal lines, respectively. Similarly, in the front-side interconnect structure 200, the IMD layer 210, the vias VG, V0, V1 and V2, and the metal lines M1, M2 and M3 may also be referred to as the front-side IMD, the front-side vias, and the front-side metal lines, respectively. The front-side IMD layer 210 may provide electrical insulation as well as structural support for the various features in the front-side interconnect structure 200. Similarly, the IMD layer 310 may provide electrical insulation as well as structural support for the various features in the back-side interconnect structure 300. Other embodiments may include more or fewer metallization layers and corresponding more or fewer number of vias. The metal line illustrated here just for an example, and the metal line may be otherwise oriented (rotated 90 degrees or at other orientations).

In some embodiments, the via VG is connected to the gate structures (gate electrodes) of the transistors, and the via VG is also referred to as the gate via, or respectively referred to as the front-side gate via. In some embodiments, the vias and metal lines in the IMD layer 310 are used for the connections of the features of the transistor. In some embodiments, the vias and metal lines in the IMD layer 310 are connected to voltage sources (or power sources) (not shown) to provide voltages to the transistors in the device region 100.

The formation of the back-side interconnect structure 300 may include removing a substrate of the device region 100 in a CMP process, forming a back-side dielectric layer under the device region 100, and forming back-side contacts connected to the source features in the device region 100 in the back-side dielectric layer. The formation of the back-side interconnect structure 300 may further include forming a first dielectric layer of the IMD layer 310 under the back-side dielectric layer, forming back-side first level vias (e.g., the vias B_V0) in the first dielectric layer, and forming a second dielectric layer of the IMD layer 310 under the first dielectric layer. The formation of the back-side interconnect structure 300 may further include forming back-side first level metal lines (e.g., the metal lines B_M1) in the second dielectric layer, forming a third dielectric layer of the IMD layer 310 under the second dielectric layer, forming back-side second level vias (e.g., the via B_V1) in the third dielectric layer. The formation of the back-side interconnect structure 300 may further include forming a fourth dielectric layer of the IMD layer 310 under the third dielectric layer, forming back-side second level metal lines (e.g., the metal line B_M2) in the fourth dielectric layer, and forming protection layer (may be multiple layers and include dielectric layers, poly layers, or combination) under the fourth dielectric layer.

The formation of the front-side interconnect structure 200 is similar to that of the back-side interconnect structure 300, the difference being that the formation processes of the front-side interconnect structure 200 are performed at the front side 100a of the device region 100, and they are not described in detail herein.

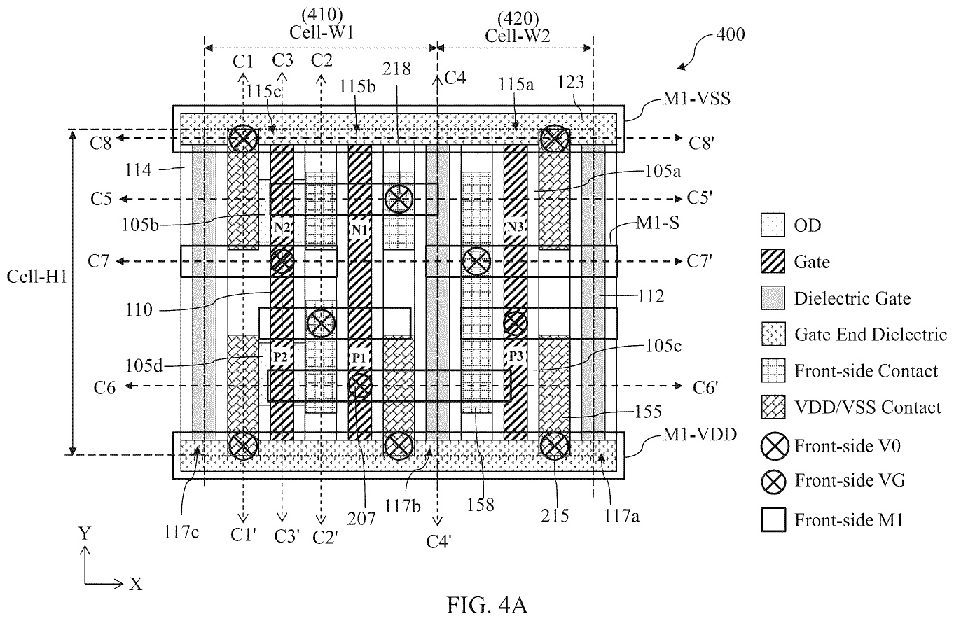

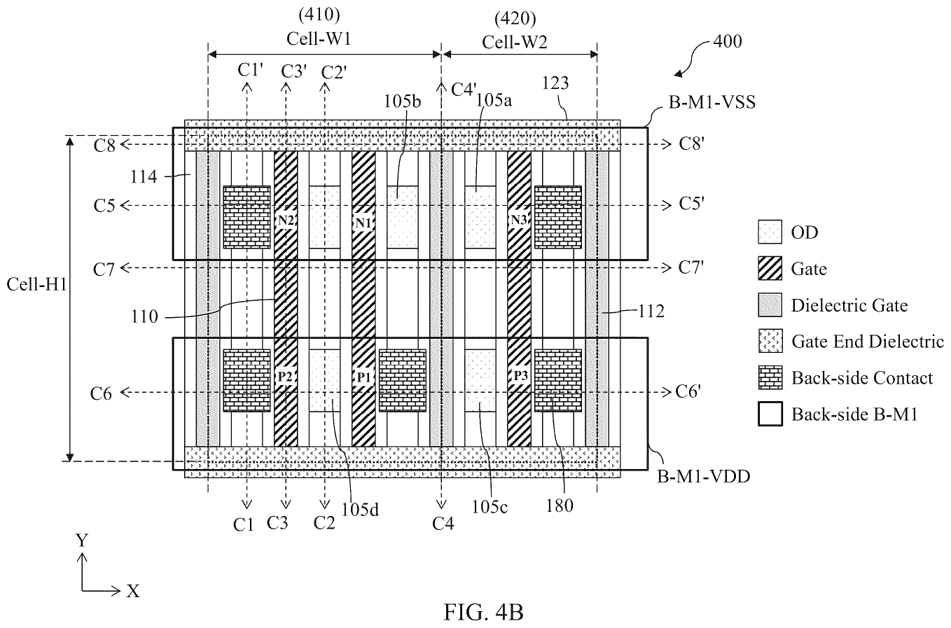

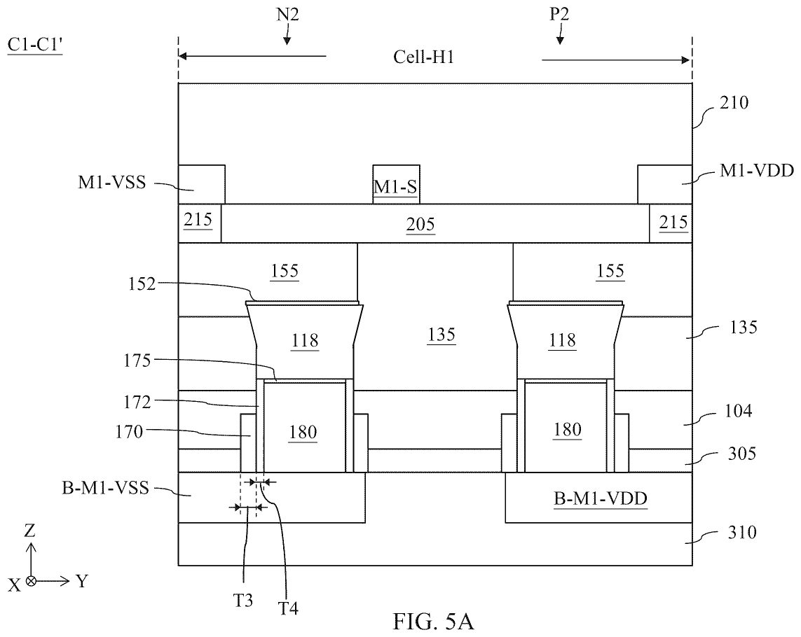

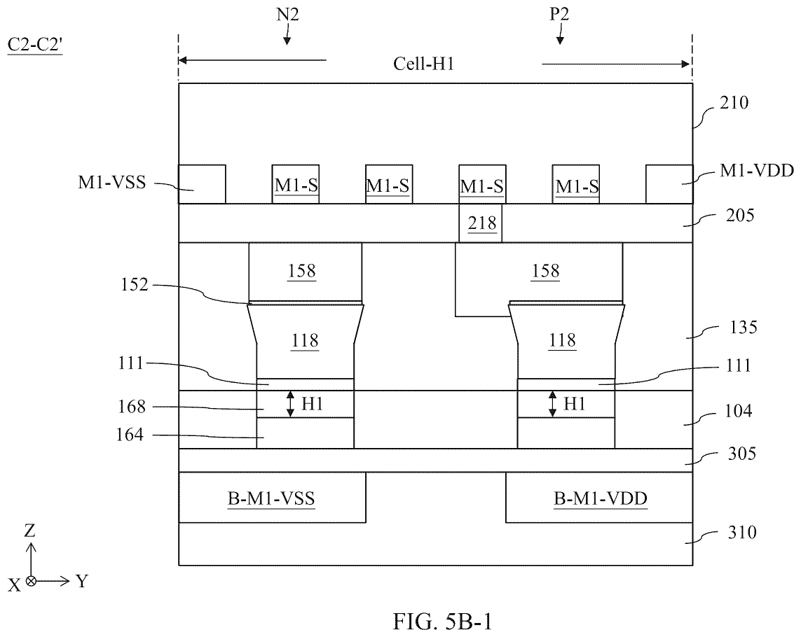

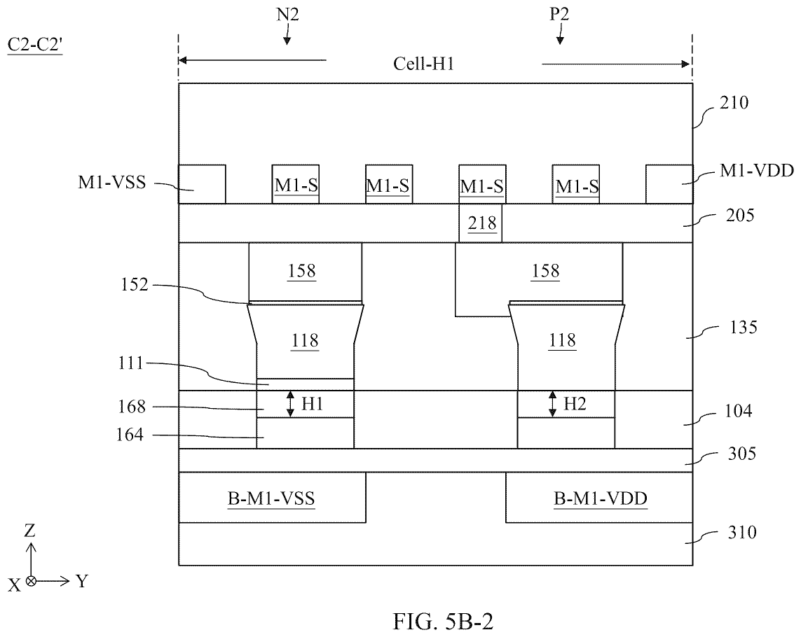

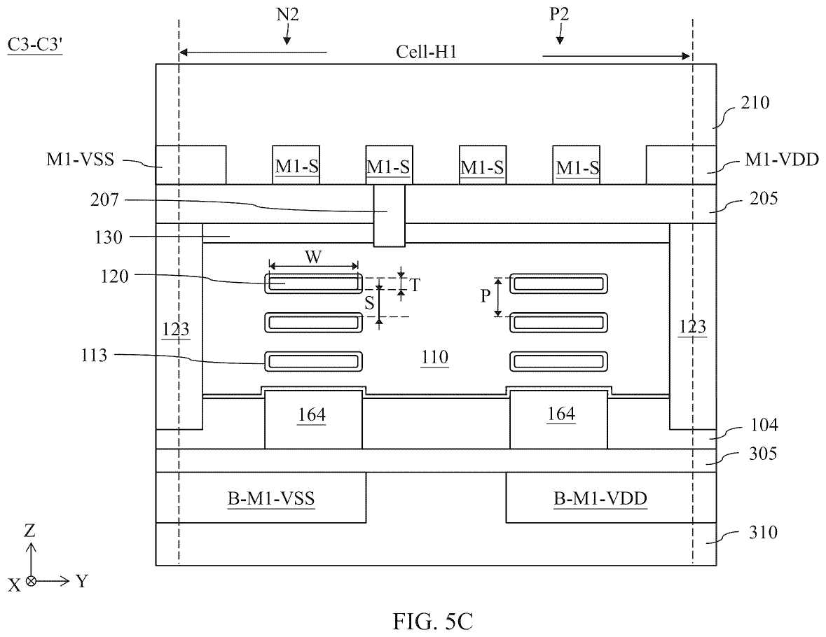

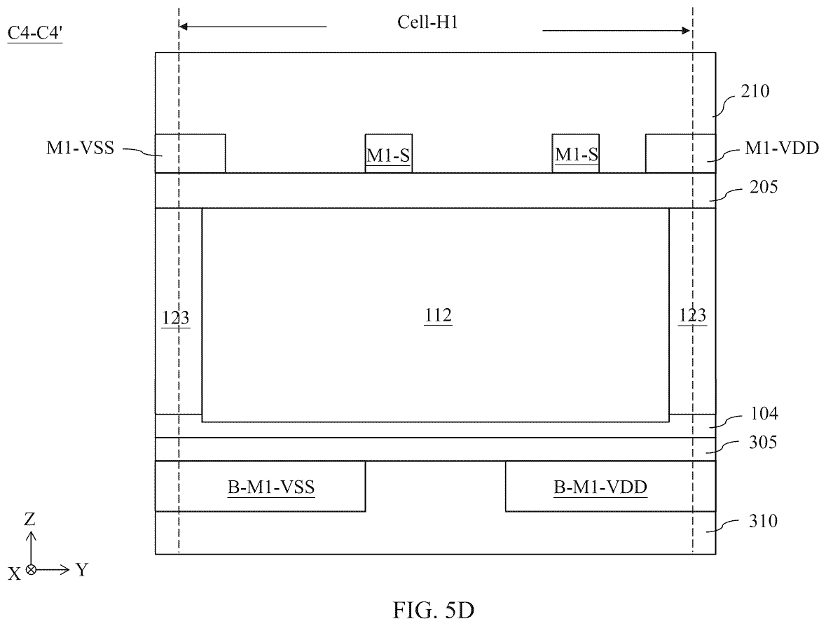

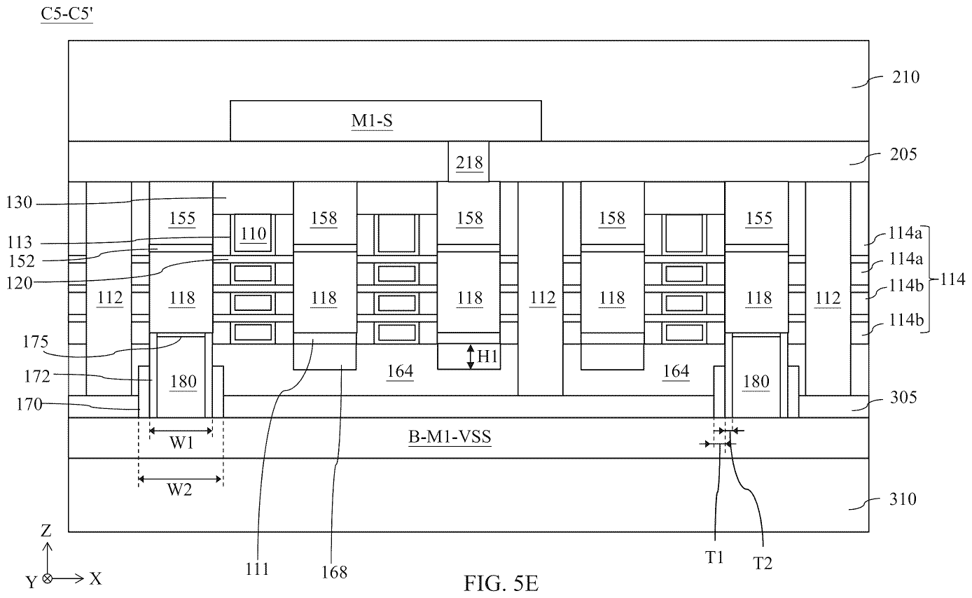

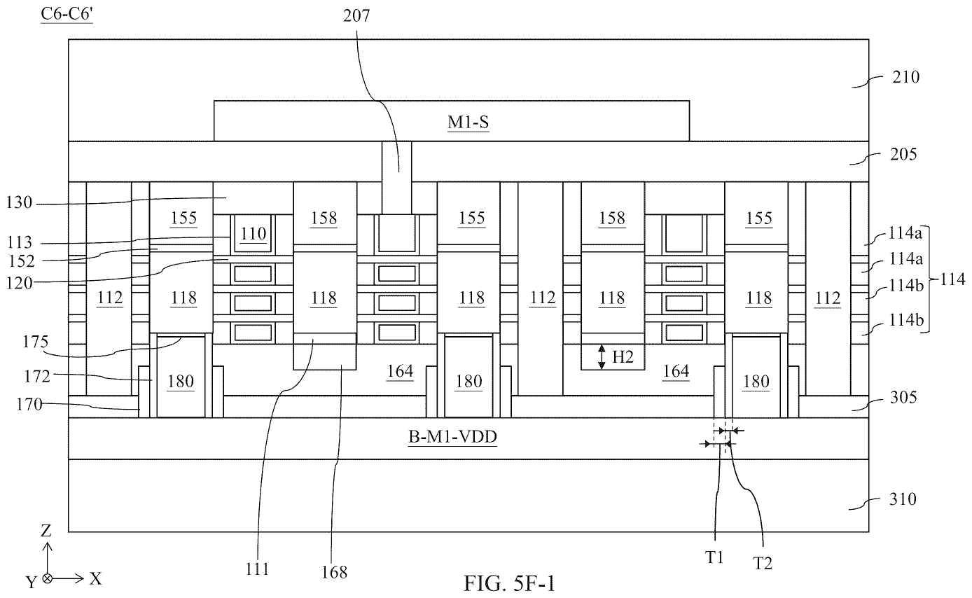

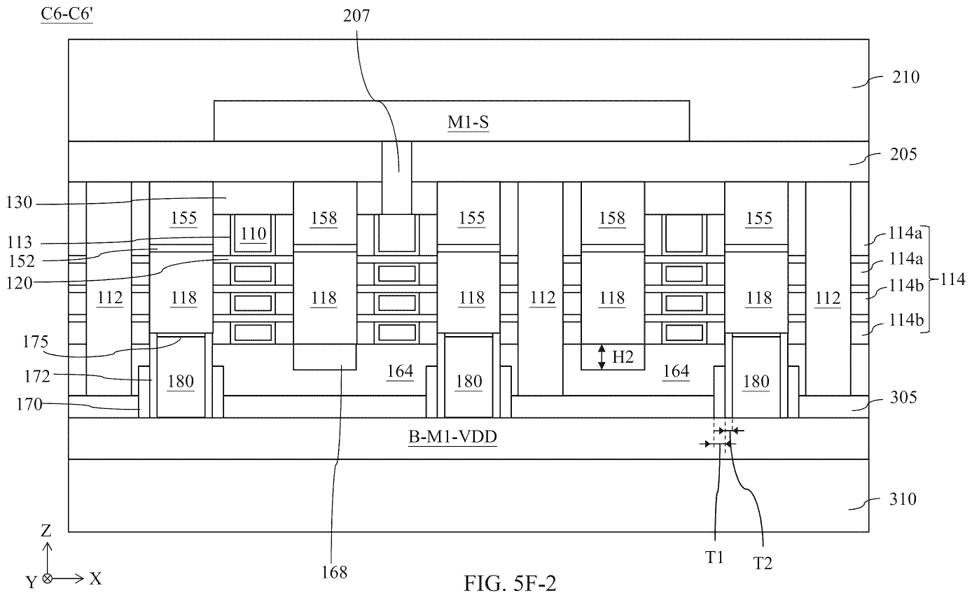

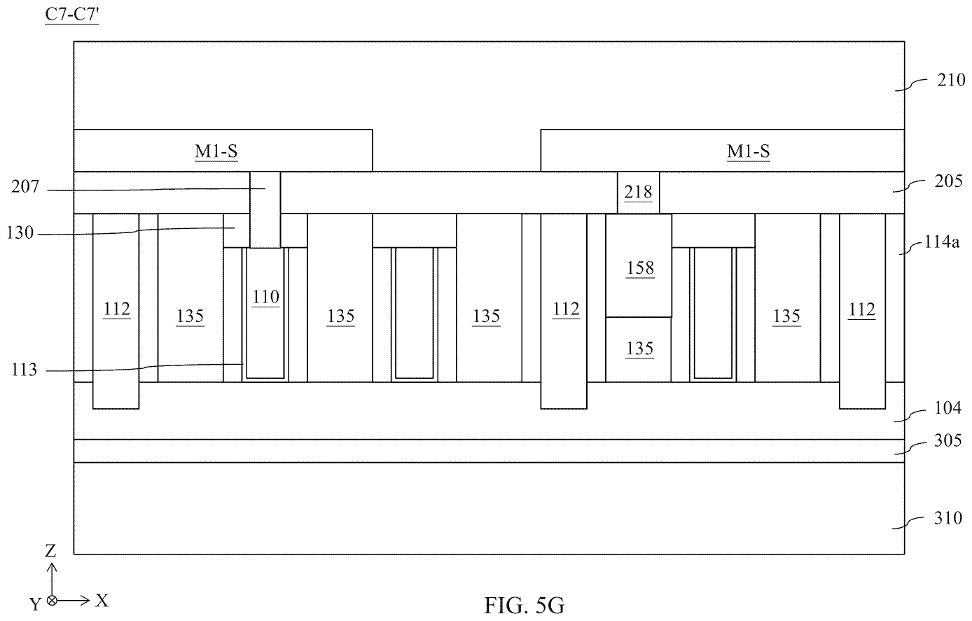

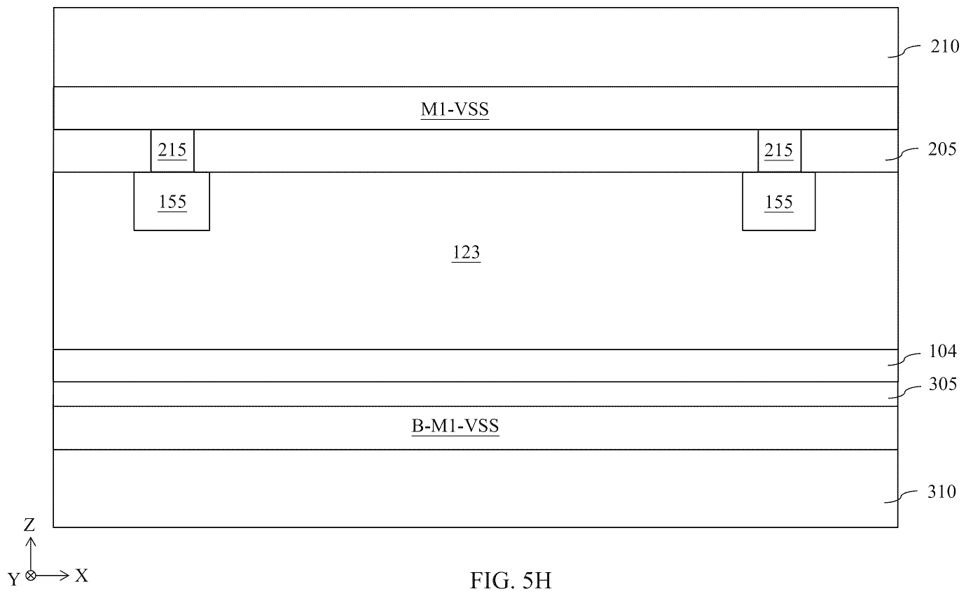

FIGS. 4A and 4B illustrate a layout diagram of a logic circuit 400 on a front side and a back-side of a semiconductor structure, respectively, in accordance with some embodiments of the disclosure. FIGS. 5A, 5B-1, 5C, 5D, 5E, 5F-1, 5G, and 5H illustrate cross-sectional views obtained from reference cross-sections C1-C1′, C2-C2′, C3-C3′, C4-C4′, C5-C5′, C6-C6′, C7-C7′, and C8-C8′ in FIGS. 4A and 4B. FIGS. 5B-2 and 5F-2 illustrate cross-sectional views of a semiconductor structure corresponding to FIGS. 5B-1 and 5F-1, respectively, in accordance with some embodiments of the disclosure.

The logic circuit 400 may include a cell array formed by the logic cells, e.g., the standard cells (also referred to STD cells). As discussed above, the STD cells may include logic devices, including but not limited to logic circuits such as inverters, NANDs, NORs, flip-flops, SACNs or a combination thereof. For the sake of providing an example, FIGS. 4A and 4B show the two logic cells 410 and 420 arranged in a row of the cell array. The logic cells 410 and 420 have the same cell height Cell-H1 in Y-axis and the different cell widths Cell-W1 and Cell-W2 (Cell-W1>Cell-W2) in X-axis. In the embodiment of FIGS. 4A and 4B, the logic cell 410 is a NAND shown in FIGS. 1A-1B and the logic cell 420 is an inverter shown in FIGS. 2A-2B. It should be understood that the logic cell 410 (including the NAND) and the logic cell 420 (including the inverter) are merely examples, and the logic circuit 400 may include more STD cells. The present disclosure applies to other types of STD cells, for example cells including NORs, ANDs, ORs, flip-flops, SCANs, or a combination thereof, or specific functional circuits, or SRAM.

The logic cell 410 includes the active regions 105b and 105d, or referred to as the oxide definition (OD) areas, and the logic cell 420 includes the active regions 105a and 105c. The active regions 105a through 105d extend in the X-axis. The logic circuit 400 further includes the gate structures 115a through 115c and the isolation structures 117a through 117c extending in the Y-axis. The gate structures 115b and 115c engage the active region 105b to form the N-type transistors N1 and N2 of the logic cell 410, and the gate structure 115a engages the active region 105a to form the N-type transistor N3 of the logic cell 420. Moreover, the gate structures 115b and 115c engage the active region 105d to form the P-type transistors P1 and P2 of the logic cell 410, and the gate structure 115a engages the active region 105c to form the P-type transistor P3 of the logic cell 420. In some embodiments, the gate structure 115a through 115c can be interchangeably referred to as a gate strip or a gate pattern.

The isolation structures 117a and 117b are arranged in the boundary of the logic cell 420, and the isolation structures 117b and 117c are arranged in the boundary of the logic cell 410. The isolation structures 117a through 117c isolate the logic cells 410 and 420, other logic cells (not shown), and other devices (not shown) from each other. In such embodiment, the isolation structures 117a through 117c are dielectric-base dummy gates. In some embodiments, the logic cells in the same row of the cell array are separated from each other by the isolation structures. For example, the logic cells 410 and 420 are separated from each other by the isolation structure 117b.

The gate structures 115a through 115c include the gate electrodes 110 and the spacers 114 formed on sidewalls of the gate electrodes 110. The isolation structures 117a through 117c include the dielectric-base gates 112 and the spacers 114 formed on sidewalls of the dielectric-base gates 112. The material of the dielectric-base gates 112 is different from that of the gate electrodes 110. In some embodiments, the dielectric-base gates 112 can be interchangeably referred to dummy gates, dummy gate pattern, dummy gate strip, isolation structures/dielectric gates serving as circuit boundaries.

In some embodiments, the dielectric-base gates 112 can be made of silicon oxide (SiOx), silicon nitride (SixNy), silicon oxynitride (SiON), dielectric material(s), other suitable material, or a combination thereof. In some embodiments, the dielectric-base gates 112 can be formed by a deposition process, such as chemical vapor deposition (CVD), physical vapor deposition (PVD), atomic layer deposition (ALD), high density plasma CVD (HDPCVD), metal organic CVD (MOCVD), or plasma enhanced CVD (PECVD).

In some embodiments, the gate end dielectric layers 123 are at ends of the gate structures 115a through 115c and ends of the isolation structures 117a through 117c. In some embodiments, the gate end dielectric layers 123 extend from the isolation structure 117a to the isolation structure 117c.

As shown in FIG. 4A illustrating the logic circuit 400 on the front side of the semiconductor structure/wafer, each gate electrode 110 is connected to an overlying level (e.g., metal line M1) through the gate via 207. Each of the active regions 105a through 105d is formed by stacked semiconductor layers 120. Source/drain regions 118 (see FIGS. 5A, 5B-1, 5B-2, 5E, 5F-1 and 5F-2) are formed on opposite sides of the semiconductor layers (or nanostructures) 120 wrapping around by the gate electrodes 110. In some embodiments, the source/drain features 118 is formed by the epitaxially-grown materials. The source/drain regions 118 (see FIGS. 5A, 5E, 5F-1 and 5F-2) which are of VDD node or VSS node can be electrically coupled to overlying power supply line M1-VDD or M1-VSS through a power supply contact 155 and a conductive via 215. The source/drain regions 118 (see 5B-1, 5B-2, 5E, 5F-1 and 5F-2) which are not of VDD node and VSS node can be electrically coupled to overlying metal lines M1-S through the source/drain contacts 158 and source/drain vias 218. In the embodiments, the metal lines other than the power supply lines M1-VDD and M1-VSS in the M1 metal layer are referred as the metal lines M1-S. The power supply contacts 155 and the source/drain contacts 158 are front-side contacts. Source/drain region(s) may refer to a source or a drain, individually or collectively dependent upon the context.

In some embodiments, the power supply line M1-VDD can be interchangeably referred to as a VDD line that is provided with positive a power supply voltage VDD, and the power supply line M1-VSS can be interchangeably referred to as a VSS line that is provided with the ground voltage VSS. In some embodiments, the cell can be powered through the positive power supply node Vdd that has a positive power supply voltage (also denoted as VDD). The cell can be also connected to power supply voltage VSS (also denoted as VSS), which may be an electrical ground. In some embodiments, the power supply line M1-VDD/M1-VSS disposed at the M1 level (e.g., the lowest metal layer in the front-side interconnect structure 200) can be interchangeably referred to a power supply landing pad or a power supply landing line. In some embodiments, the lines can be interchangeably referred to metal layers, conductive lines, conductive layers, or conductors. In some embodiments, a dopant in the source/drain regions 118 of the N-type transistors N1 through N3 may include SiP, SiC, SiPC, SiAs, Si, or a combination thereof. In some embodiments, the source/drain regions 118 of the P-type transistors P1 through P3 may include boron, BF₂, SiGe, carbon-containing material, or a combination thereof.

As shown in FIG. 4B, the logic circuit 400 on the back-side of the semiconductor structure include a back-side contact 180, and the source/drain regions 118 (see FIGS. 5A, 5E, 5F-1 and 5F-2) which are of VDD node and VSS node can be electrically coupled to the underlying power supply line B-M1-VDD/B-M1-VSS through the back-side contact 180. On the other hand, the sacrificial layers 168 can be formed between the bottom dielectric layer 111 and the semiconductor layer 164, such that the source/drain regions 118 (see 5B-1, 5B-2, 5E, 5F-1 and 5F-2) over the bottom dielectric layer 111 which are not of VDD node and VSS node can be isolated from the underlying semiconductor layers 164 and the underlying power supply line B-M1-VDD/B-M1-VSS. In some embodiments, the power supply line B-M1-VDD can be interchangeably referred to as a VDD line that is provided with positive a power supply voltage VDD, and the power supply line B-M1-VSS can be interchangeably referred to as a VSS line that is provided with the ground voltage VSS. In some embodiments, the back-side power supply lines B-M1-VDD and B-M1-VSS of the back-side interconnect structure 300 are wider than the power supply lines M1-VDD and M1-VSS of the front-side interconnect structure 200.

The semiconductor layers 120 (see FIGS. 5C, 5E, 5F-1 and 5F-2) are wrapped by the gate electrodes 110 to serve as channels or channel layers of the P-type transistors P1 through P3 and the N-type transistors N1 through N3. The P-type transistor P2 and the N-type transistor N2 has three semiconductor layers 120 vertically arranged (or stacked) in the Z-axis, as show in FIG. 5C. In some embodiments, the layer number of the semiconductor layers 120 can be in a range from about 2 to about 6. In some embodiments, gate length of the gate electrodes 110 can be in a range from about 6 nm to about 20 nm. In some embodiments, the semiconductor layers 120 have a channel width W in the Y-axis of about 4 nm to about 70 nm, a thickness T in the Z-axis of about 4 nm to about 8 nm, and a space distance S in the Z-direction of about 6 nm to about 15 nm, as shown in FIG. 5C. Furthermore, the semiconductor layers 120 have a vertical pitch P in the Z-direction of about 10 nm to about 23 nm. The vertical pitch P equals the thickness T plus the space distance S, i.e., P=T+S.

Each source/drain feature 118 (see FIGS. 5A, 5B-1, 5B-2, 5E, 5F-1 and 5F-2) is disposed between two adjacent gate structures and connect (or contact) the semiconductor layers 120 of the transistors Therefore, each source/drain feature 118 is shared by two adjacent gate structures. In some embodiments, the source/drain features 118 may be also referred to as common source/drain features. As described above, the source/drain features 118 is formed by growing a plurality of epitaxial patterns on opposite sides of the semiconductor layer 120.

As shown in FIGS. 5B-1, 5B-2, 5C, 5E, 5F-1 and 5F-2, the semiconductor layer 164 is formed to underlie the semiconductor layer 120 and extending in X-axis. Specifically, the semiconductor layer 164 is formed as a fin-like structure underlying the semiconductor layer 120. In some embodiment, the semiconductor layer 164 may be a pure semiconductor layer without dopant. In some embodiment, the semiconductor layer 164 may be doped with a dopant, and the dopant can be either N-type or P-type doping species. In some embodiments, the semiconductor layer 164 extends from one of the dielectric-base gates 112 across the gate electrodes 110 to another one of the dielectric-base gates 112. In some embodiments, the dielectric-base gate 112 penetrates the semiconductor layer 164 and is in contact with the underlying inter-layer dielectric (ILD) layer 305. The back-side power supply lines B-M1-VDD and B-M1-VSS are on the back-side of the back-side layer ILD 305. In some embodiments, the semiconductor layer 164 can be interchangeably referred to as a bottom silicon region, a doped silicon layer, a semiconductor strip, a fin, fin structure, or a fin pattern.

In some embodiments, a front-side silicide layer 152 (see FIGS. 5A, 5B-1, 5B-2, 5E, 5F-1 and 5F-2) can be formed between the source/drain contacts 158 and the source/drain regions 118 and/or between the power supply contacts 155 and the source/drain regions 118 for resistance-capacitance (RC) delay reduction. In some embodiments, a back-side silicide layer 175 (see FIGS. 5A, 5E, 5F-1 and 5F-2) can be formed between the back-side contact 180 and the source/drain regions 118 for RC delay reduction. In some embodiments, a metal silicidation process can be performed on the source/drain region 118 to form the front-side silicide layer 152 and/or the back-side silicide layer 175.

The gate top dielectric layers 130 (see FIGS. 5C, 5E, 5F-1, 5F-2 and 5G) are formed over the gate electrodes 110. In some embodiments, the gate top dielectric layer 130 can be interchangeably referred to a hard mask layers. In some embodiments, the gate top dielectric layers 130 is made of a different material than the dielectric-base gate 112. In some embodiments, the material of gate top dielectric layers 130 are selected from a group consisting of oxide, SiOC, SiON, SiOCN, nitride base dielectric, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), or combination. In some embodiments, the thickness of the gate top dielectric layer 130 is in a range from about 2 nm to about 60 nm.

The gate end dielectric layers 123 (see FIGS. 5C, 5D and 5H) have an extension depth in the STI structure 104, and the extension depth is in a range from about 5 nm to about 60 nm in Z-axis. In some embodiments, the gate end dielectric layer 123 may be made of dielectric material, such as SiO₂, Si₃N₄, SiON, SiOC, SiOCN base dielectric material, or combinations thereof. In some embodiments, the gate end dielectric layer 123 may be made of an oxide, a nitride-based material, such as Si₃N₄, SiON, or a carbon-based material, such as SiC, SiOC, SiOCN, or combinations thereof. In some embodiments, the gate end dielectric layer 123 may be made of a material having a dielectric constant greater than about 9 (e.g., high dielectric constant (high-k) material). For example, the gate end dielectric layer 123 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof.

As shown in FIGS. 5A, 5B-1, 5B-2 and 5G, an inter-layer dielectric (ILD) layer 135 is formed between the gate electrodes 110 and between the source/drain regions 118. An ILD layer 205 is formed over the gate top dielectric layers 130 and the ILD layer 135 and laterally surrounds the gate vias 207 and the source/drain vias 215 and 218. An inter-metal dielectric (IMD) layer 210 is formed over the ILD layer 205 and can provide electrical insulation as well as structural support for the various features therein, such as the metal line M1-S and the power supply lines M1-VDD and M1-VSS. In some embodiments, the ILD layer 135, the ILD layer 205, and/or the IMD layer 210 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like.

As shown in FIGS. 5B-1, 5B-2, 5E, 5F-1 and 5F-2, the sacrificial layers 168 are formed to electrically isolate the source/drain regions 118 from the underlying semiconductor layers 164 and the underlying power supply line B-M1-VDD/B-M1-VSS. In some embodiments, the sacrificial layer 168 may include SiGe. In some embodiments, the sacrificial layer 168 may be a dielectric layer or include the material different from the semiconductor layer 164.

In some embodiments, a dielectric material is selectively formed on all of the bottoms of the source/drain recess where source/drain regions 118 will be subsequently formed thereon. In some embodiments, the source/drain recess has a bottom that is in a position lower than a bottommost one of the semiconductor layers 120 about a vertical dimension in Z-axis. By way of example but not limitation, the vertical dimension H1 of N-type transistor and the vertical dimension H2 of P-type transistor can be in a range from about 10 nm to about 100 nm. The vertical dimension H1 may be equal to or different from the vertical dimension H2. Furthermore, a selective deposition process may include a deposition step to deposit the dielectric material over the semiconductor layers 120 and a sputter step to remove the dielectric material deposited on sidewalls of the source/drain recesses and an upper surface above the semiconductor layers 120, so as to leave the deposited dielectric material on the semiconductor layer 164. Subsequently, a bottom dielectric layer 111 is selectively formed over the sacrificial layer 168, and the source/drain region 118 is formed on the semiconductor layer 120 and vertically self-aligns with the bottom dielectric layer 111 in the source/drain recess. In some embodiments, the dimension of the bottom dielectric layer 111 is less than the vertical dimensions H1 and H2 in Z-axis. In some embodiments, in the P-type transistors, no bottom dielectric layer 111 is formed, and the layer and the source/drain region 118 is directly landed on the sacrificial layer 168, as shown in FIGS. 5B-2 and 5F-2.

In some embodiments, the bottom dielectric layer 111 has a vertically thickness in Z-axis, and the vertically thickness can be in a range from about 1 nm to about 20 nm. In some embodiments, the material of the bottom dielectric layer 111 includes oxide (SiO₂) base, or combined with Nitrogen-content (SiON), or Carbon-content (SiOC, SIOCN), or Nitride-base (SiN, Si₃N₄), or high-K dielectric (K>7.9), or combination.

The gate dielectric layer 113 wraps around the semiconductor layers 120, and the gate electrode 110 wraps around the gate dielectric layer 113, as shown in FIGS. 5C, 5E, 5F-1, 5F-2 and 5G. The gate electrode 110 may include a metal-containing material such as titanium nitride, titanium oxide, tungsten, cobalt, ruthenium, aluminum, combinations thereof, multi-layers thereof, or the like. Although a single-layered gate electrode 110 is illustrated, as will be subsequently described in greater detail, the gate electrode 110 may include any number of work function tuning layers, any number of barrier layers, any number of glue layers, and a fill material. In some embodiments, the gate electrode 110, the power supply lines M1-VDD and M1-VSS, the metal lines M1-S, the conductive vias 215, the power supply contacts 155, the source/drain contacts 158 and the gate vias 207 may be made of a material selected from a group including TiN, TaN, TiAl, TiAlN, TaAl, TaAlN, TaAlC, TaCN, WNC, Co, Ni, Pt, W, or combinations thereof.

The spacers 114 (see FIGS. 5E, 5F-1, 5F-2 and 5G) are formed on sidewalls of the gate dielectric layer 113 and the dielectric-base gate 112. The spacers 114 include the top spacers 114a and the inner spacers 114b. The top spacers 114a are over the semiconductor layers 120 and on top sidewalls of the gate structures 115a through 115c and the isolation structures 117a through 117c. The top spacers 114a may include multiple dielectric materials and be selected from a group consist of SiO₂, Si₃N₄, carbon doped oxide, nitrogen doped oxide, porous oxide, air gap, or, or a combination thereof.

The inner spacers 114b are between the semiconductor layers 120. The inner spacers 114b may include a dielectric material having higher K value (dielectric constant) than the top spacers 114a and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), air gap, or a combination thereof. In some embodiments, the top spacers 114a and the inner spacers 114b have a thickness in the X-direction of about 4 nm to about 12 nm.

The shallow trench isolation (STI) structure 104 (see FIGS. 5A, 5B-1, 5B-2, 5C, 5D, 5G and 5H) is formed to laterally surround the semiconductor layer 164. In some embodiments, the STI structure 104 is located between the N-type transistor and the P-type transistor. In some embodiments, the top surface of the STI structure 104 is coplanar (within process variations) with a front-side surface of the semiconductor layer 164. In some embodiments, the top surface of the STI structure 104 is above or below the front-side surface of the semiconductor layer 164. In some embodiments, the semiconductor structure 164 may separate the features of adjacent devices.

The back-side contact 180 (see FIGS. 5A, 5E, 5F-1 and 5F-2) is surrounded by two-stage dielectric including the sidewall dielectric layer 170 and the sidewall dielectric layer 172. In some embodiments, the two-stage dielectric includes a first portion close to the underlying power supply line B-M1-VDD/B-M1-VSS, and a second portion close to the source/drain feature 118. In some embodiments, the first portion of the two-stage dielectric is formed by a single dielectric layer, and the second portion of the two-stage dielectric is formed by multiple dielectric layers including the single dielectric layer. For example, the back-side contact 180 and the back-side silicide layer 175 are laterally surrounded by the sidewall dielectric layer 172 (or the inner wall dielectric layer), and the sidewall dielectric layer 172 is laterally surrounded by the sidewall dielectric layer 170 (or the outer wall dielectric layer). The sidewall dielectric layer 172 extends from the back-side power supply line B-M1-VDD/B-M1-VSS to contact the source/drain region 118, and a vertical dimension of the sidewall dielectric layer 172 is greater than a vertical dimension of the sidewall dielectric layer 170 in Z-axis.

In some embodiments, the sidewall dielectric layers 170 and 172 are formed by the same or different materials. In some embodiments, the material of sidewall dielectric layers 170 and/or 172 includes oxide (SiO2) base, or combined with Nitrogen-content (SiON), or Carbon-content (SiOC, SIOCN), or Nitride-base (SiN, Si3N4), or high-K dielectric (K>7.9), or combination.

The sidewall dielectric layer 172 is thinner than the sidewall dielectric layer 170. For example, the thickness T2 of the sidewall dielectric layer 172 is less than the thickness T1 of the sidewall dielectric layer 170 in X-axis (see FIGS. 5E, 5F-1, and 5F-2). In some embodiments, the thickness T1 can be in a range from about 2 nm to about 5 nm, and the thickness T2 can be in a range from about 1 nm to about 3 nm. In some embodiments, a ratio of the thickness T1 to the thickness T2 can be in a range from about 1.5 to about 4. Similarly, the thickness T4 of the sidewall dielectric layer 172 is less than the thickness T3 of the sidewall dielectric layer 170 in Y-axis (see FIG. 5A). In some embodiments, the thickness T3 can be in a range from about 2 nm to about 5 nm, and the thickness T4 can be in a range from about 1 nm to about 3 nm. In some embodiments, a ratio of the thickness T3 to the thickness T4 can be in a range from about 1.5 to about 4. In some embodiments, the thickness T1 in X-axis is different from the thickness T3 in Y-axis for the sidewall dielectric layer 170, and the thickness T2 in X-axis is different from the thickness T4 in Y-axis for the sidewall dielectric layer 172. In some embodiments, the thickness T1 is equal to the thickness T3 for the sidewall dielectric layer 170, and the thickness T2 is equal to the thickness T4 for the sidewall dielectric layer 172.

By arranging the VDD and VSS metal lines in both the front-side interconnect structure 200 and the back-side interconnect structure 300 to provide robustness power mesh in the cell array, thereby decreasing IR drop, especially in high density and high speed applications. In some embodiments, only the VDD or VSS metal lines are arranged in the front-side interconnect structure 200.

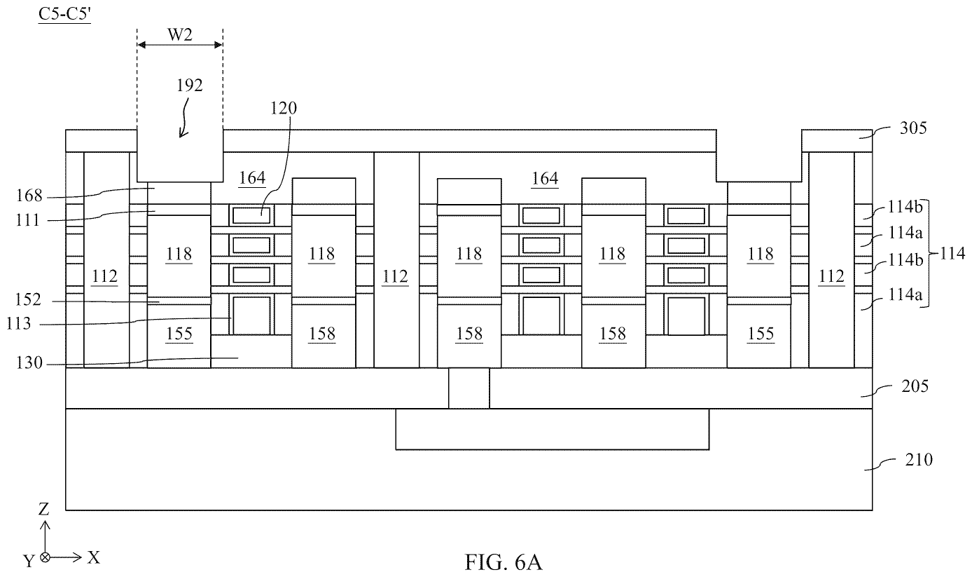

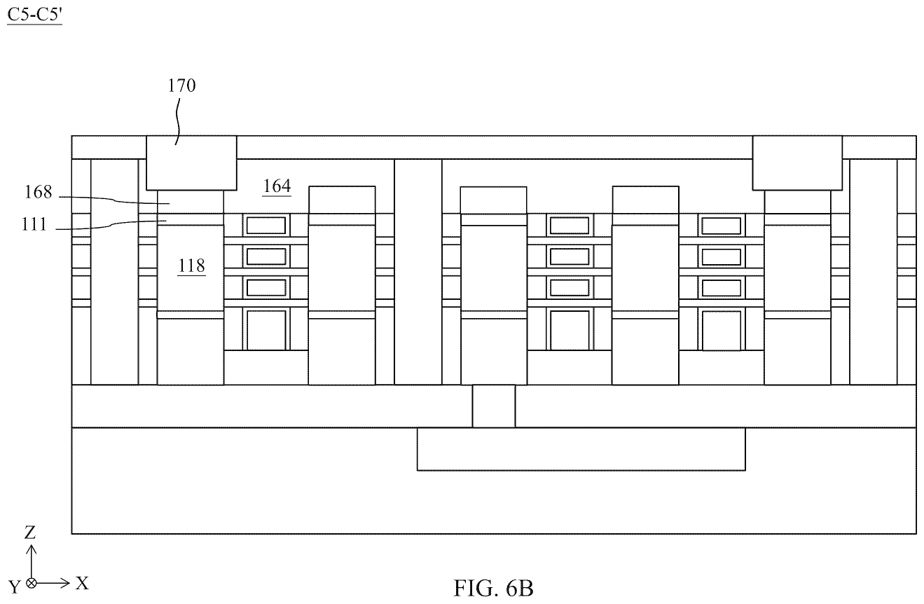

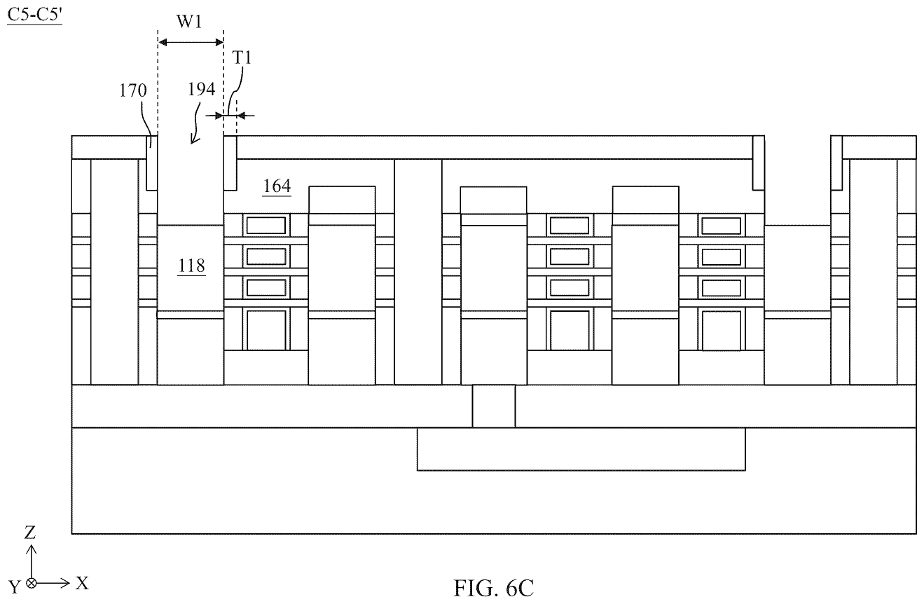

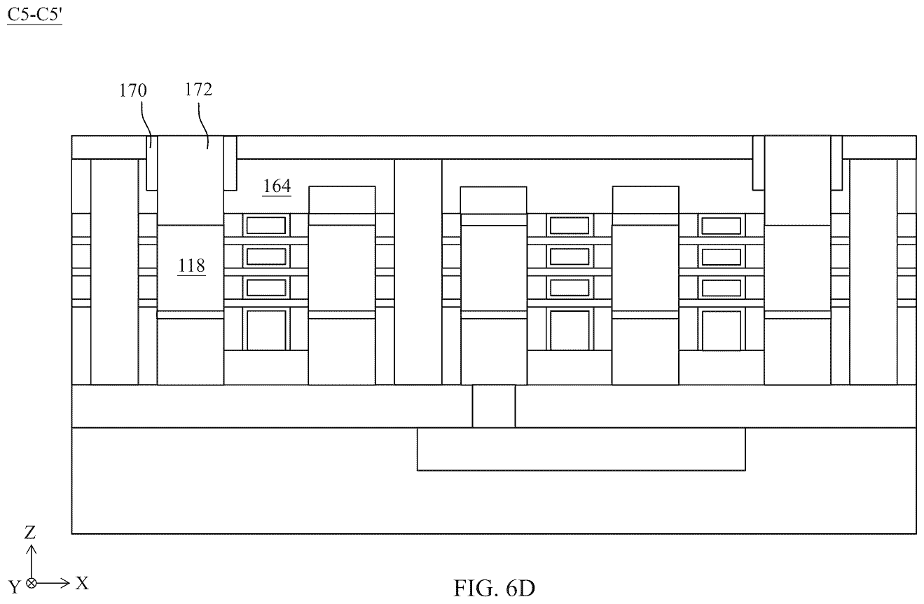

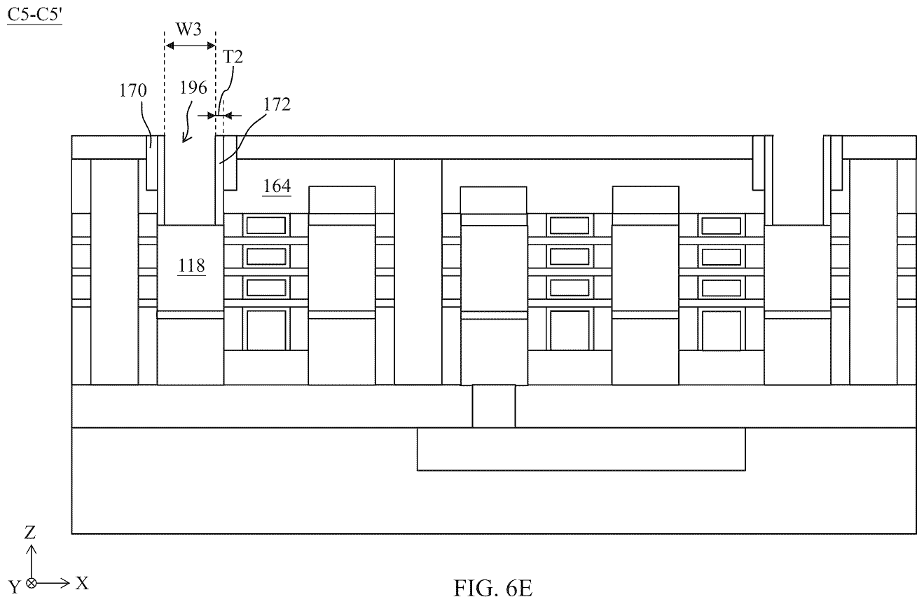

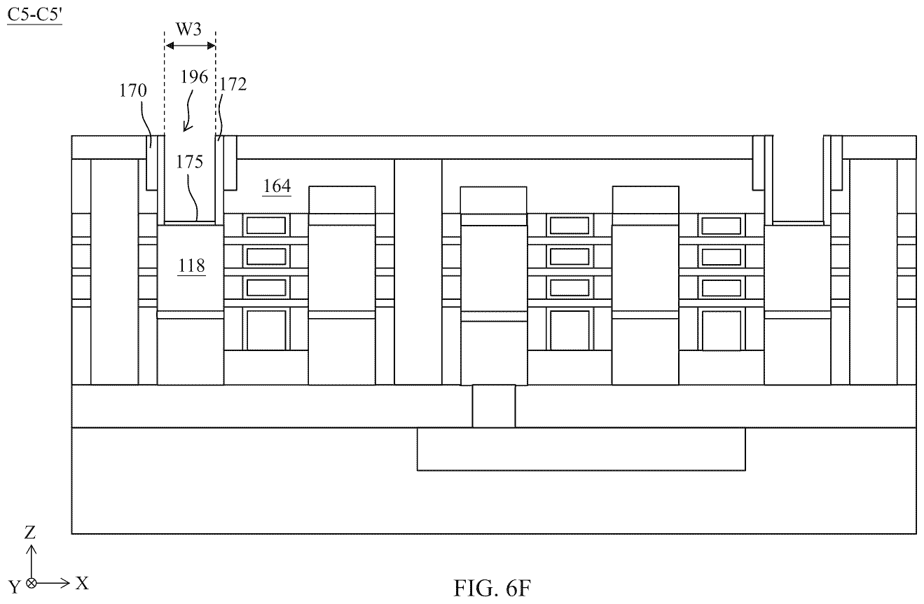

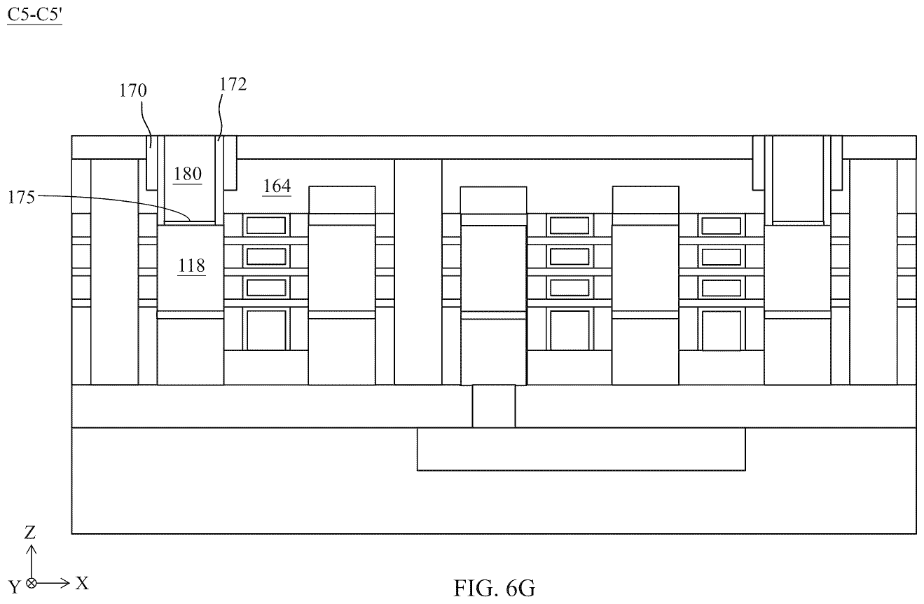

FIGS. 6A-6G illustrate cross-sectional views of intermediate stages in the formation of back-side contact 180, in accordance with some embodiments. The structures of FIGS. 6A-6G are “flipped” upside down, and a planarization process is performed, such as a chemical mechanical polish (CMP), an etch-back process, a combination thereof, to expose the semiconductor layer 164 and the STI structure 104. Subsequently, the back-side layer ILD 305 is formed on the exposed semiconductor layer 164 and the exposed STI structure 104. In some embodiments, the back-side layer ILD 305 is optional. For example, no back-side layer ILD 305 is formed between the semiconductor layer 164 and the back-side power supply lines B-M1-VDD and B-M1-VSS.

Subsequently, a first etching process can be performed to remove a portion of back-side layer ILD 305 and a portion of semiconductor layer 164 to form a back-side subsidiary contact opening 192 and expose the sacrificial layers 168, as shown in FIG. 6A, in which the sacrificial layers 168 can act as an etch stop layer. In some embodiments, the first etching process may be an anisotropic dry etch process, such as a dry etch process (e.g., RIE, a NBE, or the like). The back-side subsidiary contact opening 192 has a width W2 in the X-axis.

Subsequently, a selective deposition process can be performed to deposit the dielectric layer 170 over the sacrificial layers 168 in the back-side subsidiary contact opening 192, as shown in FIG. 6B. Subsequently, a second etching process can be performed to remove portions of the dielectric layer 170, the sacrificial layers 168 and the bottom dielectric layer 111 (optional) to form a back-side subsidiary contact opening 194 and expose the source/drain regions 118 which are of VDD node and VSS node, as shown in FIG. 6C. The back-side subsidiary contact opening 194 has a width W1 in the X-axis, and the width W1 is less than the width W2. In some embodiments, the width W1 is in a range from about 6 nm to about 20 nm, and the width W2 is in a range from about 12 nm to about 40 nm.

Subsequently, a selective deposition process can be performed to deposit the dielectric layer 172 over the source/drain regions 118 in the back-side subsidiary contact opening 194, as shown in FIG. 6D. Subsequently, a third etching process can be performed to remove the dielectric layers 172 and the bottom dielectric layer 111 (if have), in which the source/drain regions 118 can act as an etch stop layer, such that a back-side subsidiary contact opening 196 can be formed to self-align with the source/drain regions 118, as shown in FIG. 6E. The back-side subsidiary contact opening 196 has a width W3 in the X-axis, and the width W3 is less than the width W2. Subsequently, a back-side silicide layer 175 is formed over the source/drain regions 118 in the back-side subsidiary contact opening 196, as shown in FIG. 6F. Subsequently, a metal material is formed over the back-side silicide layer 175 in the back-side subsidiary contact opening 196 to form the back-side contact 180, as shown in FIG. 6G.

In the self-aligned back-side contact structure, the sacrificial layers 168 has higher etch selective to the semiconductor layer 164. Furthermore, the back-side subsidiary contact opening 192 with larger lithography size (e.g., the width W1) can avoid lithography mis-alignment that will induce process margin issue. Furthermore, the dielectric layer 170 is selectively re-filled to narrower down the over-size problem. Moreover, the sacrificial layers 168 is selectively removed and the dielectric layer 172 is formed to enlarge the isolation margin between the back-side contact 180 and the gate electrode 110. Therefore, by using the self-aligned back-side contact structure including the two-stage dielectric formed by the dielectric layers 170 and 172, the isolation margin between the back-side contact 180 and the gate electrode 110 is solved, thereby allowing continuous contact poly pitch (CPP) scaling.

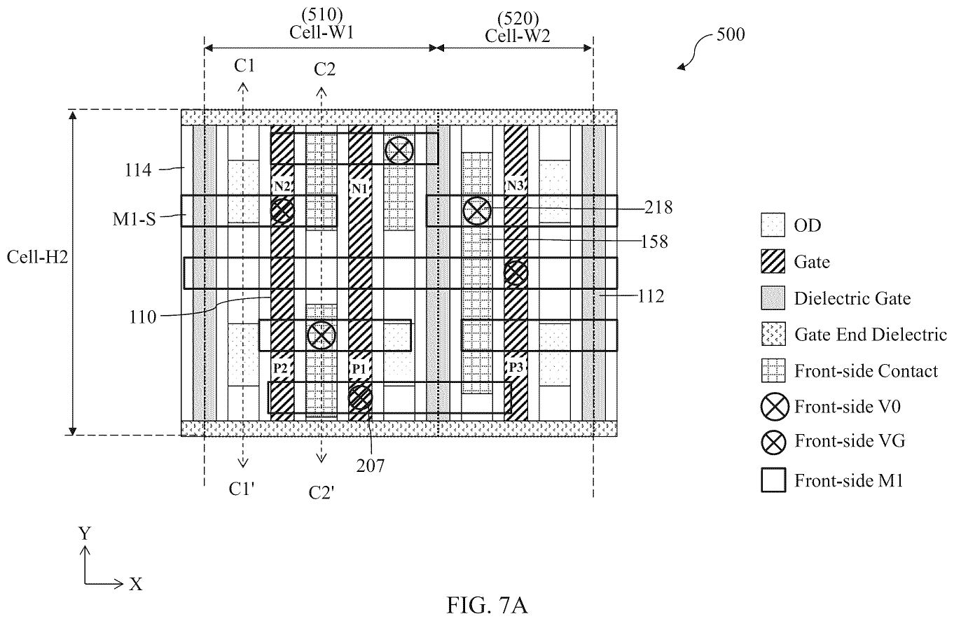

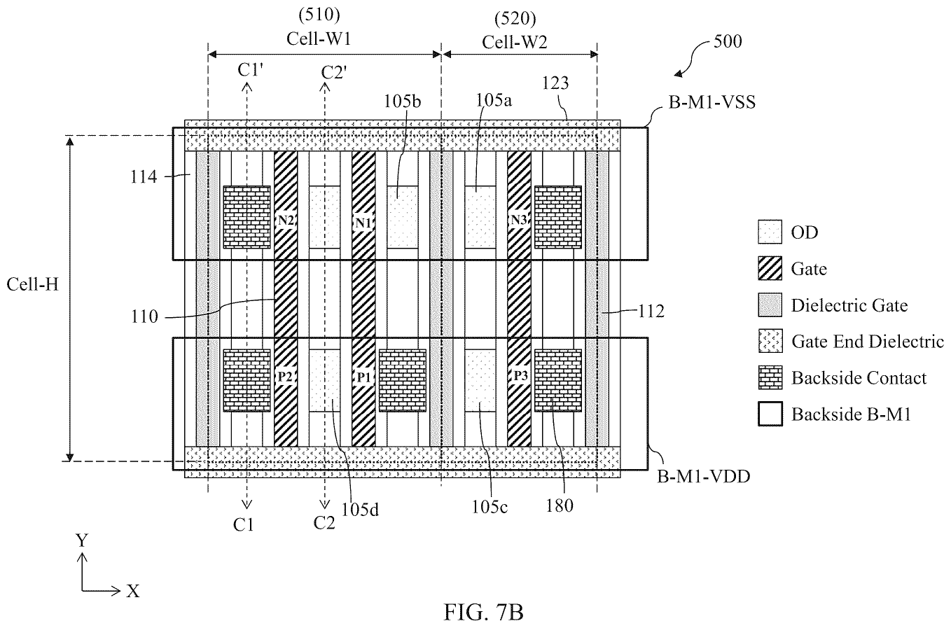

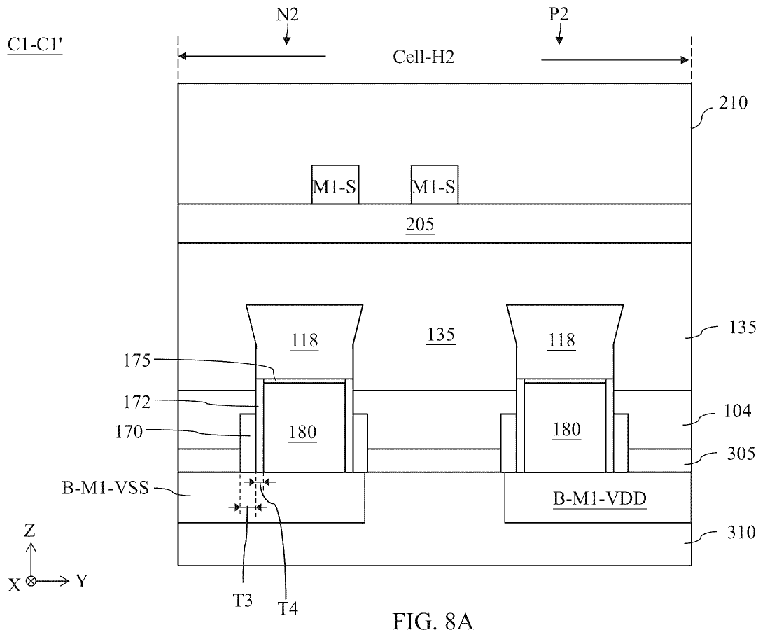

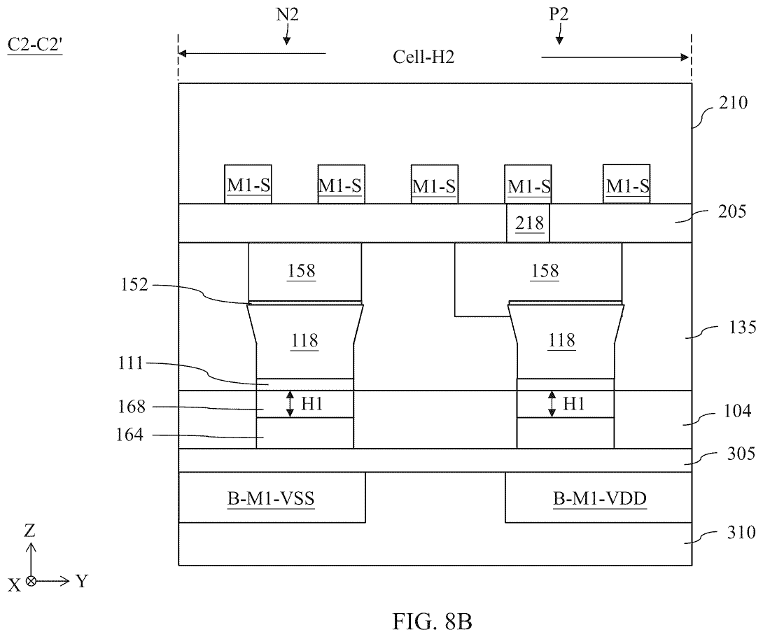

Reference is made to FIGS. 7A, 7B, 8A, and 8B. FIGS. 7A and 7B illustrate a layout diagram of a logic circuit 500 on a front side and a back-side of a semiconductor structure, respectively, in accordance with some embodiments of the present disclosure. FIGS. 8A and 8B illustrate cross-sectional views obtained from reference cross-sections C1-C1′ and C2-C2′, respectively, in FIGS. 7A and 7B. The logic circuit 500 includes the two logic cells 510 and 520. In some embodiments, the logic cell 510 is a NAND shown in FIGS. 1A-1B, and the logic cell 520 is an inverter shown in FIGS. 2A-2B. In such embodiment, the logic circuits 400 and 500 have the same circuit configuration and different structures. For example, FIGS. 7A, 7B, 8A, and 8B show an embodiment of the semiconductor structure with a different metal line routing configuration than the semiconductor structure in FIGS. 4A, 4B and 5A-5H. In addition, the present disclosure may repeat reference numerals and/or letters in the various examples. This repetition is for the purpose of simplicity and clarity and does not in itself dictate a relationship between the various embodiments and/or configurations discussed. In some embodiments, in the P-type transistors, no bottom dielectric layer 111 is formed, and the layer and the source/drain region 118 is directly landed on the sacrificial layer 168.

It is noted that, the difference between the semiconductor structures of the logic circuit 400 and 500 is in that the front-side interconnect structure 200 of the logic circuit 500 is free of power supply lines M1-VDD and M1-VSS, the conductive vias 215, and the power supply contacts 155 associated with the power supply lines M1-VDD and M1-VSS. The logic cells 510 and 520 have the same cell height Cell-H2 in Y-axis and the different cell widths Cell-W1 and Cell-W2 (Cell-W1>Cell-W2) in X-axis. In some embodiments, the cell height Cell-H2 is equal to the cell height Cell-H1. In some embodiments, the cell height Cell-H2 is less than the cell height Cell-H1 since the metal lines and contact/via features of the power supply VDD/VSS are only arranged in the back-side interconnect structure 300, there decreasing the routing complexity in the front-side interconnect structure 200.

By arranging the VDD and VSS voltage metal lines in the back-side interconnect structure 300 to reduce the routing loading in the front-side interconnection structure 200, thereby improving circuit density for the logic cells. The less metal lines in the same area (layer) also benefits the metal conductor RC performance (can be set for either Lower Resistance (wider width) or lower capacitance (larger space), or both), so as to decrease the RC delay and power IR drop.

According to some embodiments, a semiconductor structure is provided. The semiconductor structure includes a transistor, a first contact and a first power supply line. The transistor includes a gate structure having a plurality of semiconductor layers extending along a first direction and vertically stacked along a second direction in a device region, and a first source/drain region and a second source/drain region on opposite sides of the gate structure. The first contact is formed on a back-side of the first source/drain region. The first power supply line is formed on a back-side of the device region and electrically connected to the first contact. A first dielectric layer is in contact with sidewall of the first contact, and the first dielectric layer extends from the first power supply line to contact the first source/drain region. A second dielectric layer is in contact with sidewall of the first dielectric layer close to the first power supply line.

According to some embodiments, a semiconductor structure is provided. The semiconductor structure includes a transistor, a back-side contact, and a back-side power supply line. The transistor includes a channel region having a plurality of semiconductor layers extending along a first direction and vertically stacked along a second direction, and a first source/drain region and a second source/drain region on opposite sides of the channel region. The back-side contact is formed on a back-side of the first source/drain region. The back-side power supply line is electrically connected to the back-side contact. The back-side contact has a first portion close to the back-side power supply line and a second portion close to the first source/drain region. The first portion of the back-side contact is laterally surrounded by a single dielectric layer, and the second portion of the back-side contact is laterally surrounded by a plurality of dielectric layers.

According to some embodiments, a method for manufacturing a semiconductor structure is provided. The method includes forming a plurality of semiconductor layers arranged in a vertical direction on a semiconductor layer in a device region of the semiconductor structure, forming a plurality of sacrificial layers on the semiconductor layer, growing a plurality of epitaxial regions on opposite sides of the semiconductor layers and on the sacrificial layers, forming a gate pattern across the semiconductor layers and between the epitaxial regions, performing a planarization process on a back-side of the device region to expose the semiconductor layer, etching the semiconductor layer of a back-side of the device region to form a first opening and expose one of the sacrificial layers, forming a first dielectric layer in the first opening, etching a portion of the first dielectric layer and the one of the sacrificial layers to form a second opening, forming a second dielectric layer in the second opening, etching a portion of the second dielectric layer to form a third opening and expose one of the epitaxial regions, forming a back-side contact in the third opening, and forming a back-side power supply line on the back-side contact.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a transistor, comprising:
a gate structure having a plurality of semiconductor layers extending along a first direction and vertically stacked along a second direction in a device region; and
a first source/drain region and a second source/drain region on opposite sides of the gate structure;
a first contact formed on a back-side of the first source/drain region; and
a first power supply line formed on a back-side of the device region and electrically connected to the first contact,
wherein a first dielectric layer is in contact with sidewall of the first contact, and the first dielectric layer extends from the first power supply line to contact the first source/drain region,
wherein a second dielectric layer is in contact with sidewall of the first dielectric layer close to the first power supply line.

2. The semiconductor structure of claim 1, wherein the first dielectric layer is thinner than the second dielectric layer.

3. The semiconductor structure of claim 1, further comprising:
a silicide layer formed between the first source/drain region and the first contact,
wherein the silicide layer is laterally surrounded by the first dielectric layer.

4. The semiconductor structure of claim 1, further comprising:
a second contact on a front-side of the first source/drain region; and
a second power supply line on a front-side of the device region and electrically connected to the second contact,
wherein the second power supply line and the first power supply line extend along the first direction.

5. The semiconductor structure of claim 4, wherein the first power supply line is wider than the second power supply line.

6. The semiconductor structure of claim 1, further comprising:
a second contact on a front-side of the second source/drain region; and
a first metal line on a front-side of the device region and electrically connected to the first contact,
wherein the first metal line and the first power supply line extend along the first direction.

7. The semiconductor structure of claim 6, further comprising:
a sacrificial layer over a back-side of the second source/drain region.

8. The semiconductor structure of claim 7, further comprising:
a dielectric layer formed between the second source/drain region and the sacrificial layer.

9. The semiconductor structure of claim 8, wherein a dimension of the sacrificial layer is greater than a height of the dielectric layer in the second direction.

10. The semiconductor structure of claim 6, further comprising:
a sacrificial layer on a back-side of the second source/drain region,
wherein the transistor is an N-type transistor, and the sacrificial layer is separated from the second source/drain region by a bottom dielectric layer.

11. The semiconductor structure of claim 6, further comprising:
a sacrificial layer on a back-side of the second source/drain region,
wherein the transistor is a P-type transistor, and the sacrificial layer is in contact with the second source/drain region.

12. A semiconductor structure, comprising:
a transistor, comprising:
a channel region having a plurality of semiconductor layers extending along a first direction and vertically stacked along a second direction; and
a first source/drain region and a second source/drain region on opposite sides of the channel region; and
a back-side contact formed on a back-side of the first source/drain region; and
a back-side power supply line electrically connected to the back-side contact,
wherein the back-side contact has a first portion close to the back-side power supply line and a second portion close to the first source/drain region,
wherein the first portion of the back-side contact is laterally surrounded by a single dielectric layer, and the second portion of the back-side contact is laterally surrounded by a plurality of dielectric layers.

13. The semiconductor structure of claim 12, wherein the plurality of dielectric layers comprises the single dielectric layer.

14. The semiconductor structure of claim 12, further comprising:
a back-side silicide layer between the first source/drain region and the back-side contact,
wherein the back-side silicide layer is surrounded by the single dielectric layer, the back-side contact and the first source/drain region.

15. The semiconductor structure of claim 12, further comprising:
a front-side contact on a front-side of the first source/drain region; and
a front-side power supply line electrically connected to the front-side contact,
wherein the front-side power supply line and the back-side power supply line extend along the first direction, and the back-side power supply line is wider than the front-side power supply line.

16. The semiconductor structure of claim 12, further comprising:
a front-side contact on a front-side of the second source/drain region; and
a front-side metal line electrically connected to the front-side contact,
wherein the front-side metal line and the back-side power supply line extend along the first direction.

17. The semiconductor structure of claim 16, further comprising:
a sacrificial layer over a back-side of the second source/drain region; and
a dielectric layer formed between the second source/drain region and the sacrificial layer.

18. A method for manufacturing a semiconductor structure, comprising:
forming a plurality of semiconductor layers arranged in a vertical direction on a semiconductor layer in a device region of the semiconductor structure;
forming a plurality of sacrificial layers on the semiconductor layer;
growing a plurality of epitaxial regions on opposite sides of the semiconductor layers and on the sacrificial layers;
forming a gate pattern across the semiconductor layers and between the epitaxial regions;
performing a planarization process on a back-side of the device region to expose the semiconductor layer;
etching the semiconductor layer of the back-side of the device region to form a first opening and expose one of the sacrificial layers;
forming a first dielectric layer in the first opening;
etching a portion of the first dielectric layer and the one of the sacrificial layers to form a second opening;
forming a second dielectric layer in the second opening;
etching a portion of the second dielectric layer to form a third opening and expose one of the epitaxial regions;
forming a back-side contact in the third opening; and
forming a back-side power supply line on the back-side contact.

19. The method of claim 18, wherein forming the back-side contact in the third opening further comprises:
forming a silicide layer in the third opening and over the one of the epitaxial regions; and
forming the back-side contact in the third opening and over the silicide layer.

20. The method of claim 18, further comprising:
forming a front-side contact on the one of the epitaxial regions; and
forming a front-side power supply line on the front-side contact.
